(19) United States
(12) Patent Application Publication
(10) Pub. No.: US 2006/0249745 A1
(43) Pub. Date: Nov. 9, 2006

(54) Heat dissipating structure and light emitting device having the same

(75) Inventors: Su-hee Chae, Suwon-si (KR); Tae-hoon Jang, Seoul (KR); Hyung-kun Kim, Suwon-si (KR); Youn-joon Sung, Yongin-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/387,864

(22) Filed: Mar. 24, 2006

(30) Foreign Application Priority Data
May 6, 2005 (KR) 10-2005-0037852

(51) Int. Cl. H01L 33/00

(52) U.S. Cl. 257/99; 257/706; 257/707; 257/E33.057; 257/E33.075

(57) ABSTRACT

A heat dissipating structure is flip-chip bonded to a light-emitting element and facilitates heat dissipation. The heat dissipating structure includes: a submount facing the light-emitting element and having at least one groove; a conductive material layer filled into at least a portion of the at least one groove; and a solder layer interposed between the light-emitting element and the submount for bonding. The heat dissipating structure and the light-emitting device having the same allow efficient dissipation of heat generated in the light-emitting element during operation.

### CROSS-REFERENCE TO RELATED PATENT APPLICATION

Priority is claimed to Korean Patent Application No. 10-2005-0037852, filed on May 6, 2005, in the Korean Intellectual Property Office, the disclosure of which is incorporated herein in its entirety by reference.

### BACKGROUND OF THE DISCLOSURE

1. Field of the Disclosure

The present disclosure relates to a heat dissipating structure and a light-emitting device including the same, and more particularly, to a light emitting device including a light-emitting element such as a laser diode (LD) or a light-emitting diode (LED) and a heat dissipating structure that is flip-chip bonded to the light-emitting element to facilitate heat dissipation.

2. Description of the Related Art

Laser light emitted from a laser diode, one type of light-emitting element, has many practical applications in fields such as optical communications, multiple communications, and space communications. This is due in part to its small frequency bandwidth and high degree of orientation. The other major application of a laser diode is optical recording media. In compact disk players and compact disk read/write (CD-RW) drives, there is a need for a laser diode requiring a low current level as well as having a long operational life expectancy.

FIG. 1 shows an example of a conventional light-emitting device including a laser diode as a light-emitting element 80. The light-emitting element 80 is flip-chip bonded to a submount 11 of a heat dissipating element 10 for easily dissipating heat generated from the light-emitting element 80 during operation. The light-emitting element 80 includes a substrate 61, and an upper material layer 50, a resonant layer 40 and a lower material layer 30 sequentially formed beneath (as oriented in the illustration) the substrate 61. The structure of the layers formed beneath the substrate 61 is divided into a first region R₁′ and a second region R₂′ separated from the first region R₁′ by a gap G′. A p-type electrode 21 is formed as the lowermost layer 25 of the first region R₁′ while an n-type electrode 22 is formed as the lowermost layer of the second region R₂′. Upon application of a bias voltage by the p- and n-type electrodes 21 and 22, holes and electrons recombine on the resonant layer 40, resulting in the emission of light. A current limiting layer 25 is formed between the lower material layer 30 and the p-type electrode 21 and limits a channel through current flows. That is, the current limiting layer 25 is buried into all of the region of the lower material layer 30 except a ridge 30a and limits the amount of current being injected into the resonant layer 40 and improves driving efficiency.

A large amount of heat is generated in the resonant layer 40 during the operation of the laser diode and transferred to a solder layer 19 mainly through the ridge 30a, a diffusion prevention layer 17 and to the ceramic submount 11 through the solder layer 19. The heat transferred to the submount 11 is dissipated into the air by natural convection. However, because most of the heat transferred to the submount 11 tends to concentrate on region A of narrow width being in contact with the solder layer 19, it is difficult to effectively dissipate heat.

Since threshold current for light emission from a laser diode and laser mode stability decrease as temperature increases, a conventional light-emitting device suffers degradation in light emission characteristics of laser over time. Along with this problem, a high output power laser diode with high injection current also suffers restriction on increase of output power because it generates a large amount of heat.

### SUMMARY OF THE DISCLOSURE

The present disclosure provides a heat dissipating structure designed to prevent degradation of a light-emitting element while providing stable light emission characteristics and a light-emitting device having the heat dissipating structure.

According to an aspect of the present disclosure, there is provided a heat dissipating structure that is flip-chip bonded to a light-emitting element and facilitates heat dissipation, the heat dissipating structure including: a submount facing the light-emitting element and having at least one groove; a conductive material layer filled into at least a portion of the at least one groove; and a solder layer interposed between the light-emitting element and the submount for bonding. The conductive material layer may contain at least one of gold (Au), copper (Cu), copper (Cu) alloy, copper-tungsten (Cu—W) alloy, silver (Ag), and aluminum (Al) alloy.

According to another aspect of the present disclosure, there is provided a light-emitting device including: a light-emitting element including an upper material layer, a lower material layer, and a resonant layer that is interposed between the upper and lower material layers and emits light; a submount that is disposed to vertically face the light-emitting element and has at least one groove; a conductive material layer filled into at least a portion of the at least one groove; and a solder layer interposed between the light-emitting element and the submount for bonding.

The light-emitting device may further include a metal medium layer interposed between the submount and the solder layer. The metal medium layer may be formed to surround at least the inside of the groove.

The metal medium layer includes titanium (Ti), platinum (Pt), and Au. The light-emitting device may further include a diffusion prevention layer interposed between the metal medium layer and the solder layer.

The ratio of thickness t2 of the conductive material layer to thickness t1 of the submount may be greater than 46%.

The light-emitting element may include a first region containing the resonant layer and a second region that is separated from the first region by a gap. The solder layer may include a first solder layer bonded to the first region and a second solder layer bonded to the second region. The conductive material layer may vertically face at least the first region and create a heat dissipating path for dissipating heat away from the resonant layer.

In this case, the first and second regions are stacked to substantially the same thickness and the top surface of the first solder layer facing the first region are at substantially the same level as the top surface of the second solder layer facing the second region. Alternatively, the first and second regions may be formed to a different thickness and the top surfaces of the first and second solder layers may have a step height to compensate for a step difference between the first and second regions.

The submount may have a first groove formed along one direction and a plurality of second grooves arranged at predetermined intervals perpendicular to the length of the first groove.

The light-emitting element may be a laser diode (LD) or a light-emitting diode (LED). The solder layer may be formed of a Sn-based alloy such as Au/Sn or Sn/Ag. The submount may be formed of an insulating material such as aluminum nitride (AlN) or silicon carbide (SiC), aluminum (Al), and silicon (Si).

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional light-emitting device;

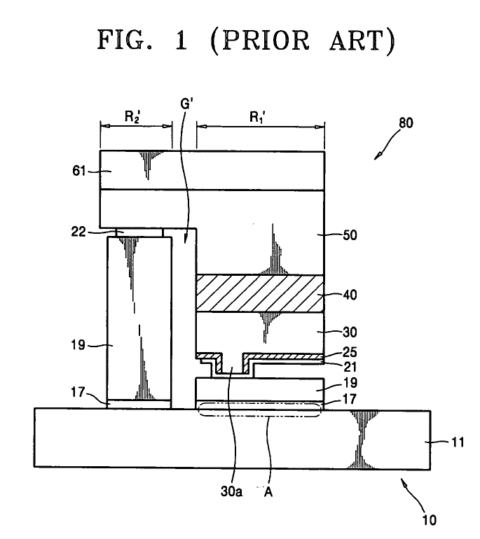

FIG. 2 is a perspective view of a light-emitting device according to a first embodiment of the present disclosure;

FIG. 3 is a perspective view of the submount shown in FIG. 2;

FIG. 4 is a perspective view of a light-emitting device according to a second embodiment of the present disclosure;

FIG. 5 is a perspective view of a light-emitting device according to a third embodiment of the present disclosure; and

FIG. 6 is a perspective view of the submount shown in FIG. 5.

### DETAILED DESCRIPTION OF THE DISCLOSURE

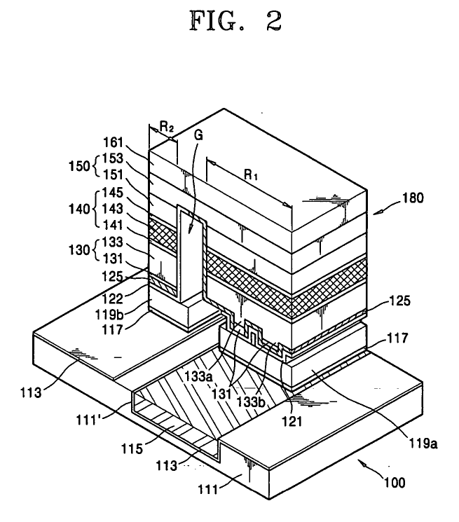

The present invention will now be described more fully with reference to the accompanying drawings, in which exemplary embodiments of the invention are shown. Referring to FIG. 2, a light-emitting device according to a first embodiment of the present disclosure includes a light-emitting element 180 and a heat dissipating structure 100 that are flip-chip bonded to vertically face each other. The light-emitting element 180 includes a substrate 161 forming a base, and an upper material layer 150, a resonant layer 140 and a lower material layer 130 sequentially formed beneath the substrate 161. Here, the structure of the layers formed beneath the substrate 161 is divided into a first area R₁ and a second area R₂ separated from the first area R₁ by a gap G.

The substrate 161 may be formed of sapphire or III-V compound semiconductor such as gallium nitride (GaN) or silicon carbide (SiC). The upper material layer 150 is formed beneath the substrate 161 and includes a first compound semiconductor layer 153 as a contact layer and an upper cladding layer 151 formed beneath the first compound semiconductor layer 153. The first compound semiconductor layer 153 may be formed of an n-GaN-based III-V nitride compound semiconductor material or other III-V compound semiconductor material enabling lasing. The gap G is formed from a portion of the first compound semiconductor layer 153 and separates the first area R₁ from the second area R₂. The upper cladding layer 151 may be formed from n-GaN/AlGaN having a refractive index or other compound semiconductor material enabling lasing.

The resonant layer 140 includes an upper waveguide layer 145, an active layer 143 and a lower waveguide layer 141 formed sequentially beneath the upper cladding layer 151 of the first compound semiconductor layer 150. The upper and lower waveguide layers 145 and 141 may be formed of a GaN-based III-V compound semiconductor material with a refractive index less than that of the active layer 143. The upper and lower waveguide layers 145 and 141 may be formed of n-GaN and p-GaN, respectively. The active layer 143 is formed of a material where light emission occurs due to hole-electron recombination. The active layer 143 may be a GaN-based III-V nitride compound semiconductor layer having a multi-quantum well (MQW) structure, more preferably, InₓAl_{y}Ga_{1-x-y}N (0<x) layer. The active layer 143 may have a single quantum well (SQW), multiple quantum well (MQW) or other commonly known structure.

A lower material layer 130 is formed beneath the lower waveguide layer 141 of the resonant layer 143. The lower material layer 130 includes a lower cladding layer 133 and a second compound semiconductor layer 131 sequentially stacked. The lower cladding layer 133 at the first area R₁ has a ridge 133a and a protrusion 133b that are separated from each other by a predetermined distance and extend downward as oriented in the illustration. The lower cladding layer 133 at the second area R₂ has a flat, smooth surface.

The lower cladding layer 133 is generally formed of a similar material to that of the upper cladding layer 151 but has different doping type than the doping type of the upper cladding layer 151. For example, when the upper cladding layer 151 is formed of n-GaN/AlGaN, the lower cladding layer 133 is generally formed of p-GaN/AlGaN. A second compound semiconductor layer 131 serving as an ohmic contact layer is formed beneath the lower cladding layer 133, more specifically, the ridge 133a and the protrusion 133b. The second compound semiconductor layer 131 is generally formed of a similar material to that of the first compound semiconductor layer 153 and has an opposite doping type to that of the first compound semiconductor layer 153. That is, when the first compound semiconductor layer 153 is generally formed of an n-type compound semiconductor material such as n-GaN, the second compound semiconductor layer 131 is formed of a p-type compound semiconductor material such as p-GaN.

A current limiting layer 125 serving as a passivation layer is formed beneath the lower material layer 130 so as to cover predetermined regions of the lower cladding layer 133 and the second compound semiconductor layer 131. More specifically, the current limiting layer 125 covers the entire second compound semiconductor layer 131 except that underlying the ridge 133a at the first area R₁ so as to expose the ridge 133a. The current limiting layer 125 is formed of a typical passivation material such as oxide containing at least one element of Si, aluminum (Al), zirconium (Zr), and tantalum (Ta), for example.

A p-type electrode 121 is formed along the bottom surfaces of the current limiting layer 125 and the second compound semiconductor layer 131 at the first area R₁ and contacts the second compound semiconductor layer 131 underlying the ridge 133a so as to conduct current. An n-type electrode 122 underlies the current limiting layer 125 at the second area R₂. The n-type electrode 122 extends through the gap G into the bottom surface of the first compound semiconductor layer 153 and is electrically connected to the first compound semiconductor layer 153.

The light-emitting element 180 having the above-mentioned configuration is flip-chip bonded to the heat dissipating structure 100. The heat dissipating structure 100 includes a submount 111 and solder layers 119a and 119b formed on the submount 111. The submount 111 acts as a heat dissipating plate and dissipates heat generated in the light-emitting element 180 producing laser light during operation. To accomplish this function, the submount 111 may be formed of a highly thermally conductive insulating material such as aluminum nitride (AlN) with thermal conductivity of 230 W/Mk, SiC with thermal conductivity of 240 W/mK, aluminum (Al), or silicon (Si).

The submount 111 has a groove 111′ extending along one direction and filled with a conductive material layer 115. Here, conductive is in a heat transfer sense, but in exemplary embodiments it is also electrically conductive The groove 111′ may be formed by a commonly known dry or wet etching method.

A metal medium layer 113 is formed on the inside of the groove 111′ and a predetermined region of the submount 111. The metal medium layer 113 is interposed between the submount 111 and the conductive material layer 115 that has poor adhesion characteristics, for good adhesion therebetween. The metal medium layer 113 formed on the inside of the groove 111′ also serves as a seed layer for filling the groove 111′ with the conductive material layer 115 and may be formed by sequentially stacking titanium (Ti), platinum (Pt), and gold (Au), for example.

The conductive material layer 115 creates a heat dissipating path across the submount 111 and contributes to fast dissipation of heat generated from the light-emitting element 180 during operation. The conductive material layer 115 is formed by plating highly thermally conductive metal such as gold (Au), copper (Cu), copper (Cu) alloy, copper-tungsten (Cu—W) alloy, silver (Ag), and aluminum (Al) alloy, for example. The thermal conductivities of Cu and Au are about 393 to 401 W/mK and 297 W/mK, respectively. The conductive material layer 115 may have higher thermal conductivity than the submount 111 for more efficient heat dissipation.

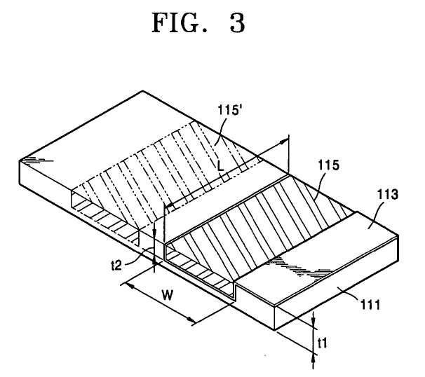

FIG. 3 is a perspective view of the submount 111. Referring to FIG. 3, the conductive material layer 115 may have a thickness t2 that is greater than 46% of thickness t1 of the submount 111 for efficient heat dissipation. For example, when the thickness t1 of the submount 111 is 150 μm, the thickness t2 of the conductive material layer 115 is greater than 70 μm in this exemplary embodiment. The conductive material layer 115 may be formed along the entire length of the submount 111. The entire length L along which the submount 111 extends may be 2,000 to 2,500 μm. Reference character W denotes the width of the conductive material layer 115 and may be, for example, about 100 μm.

The conductive material layer 115 is formed at a position corresponding to the first area R₁ where heat generated from the light-emitting element 180 during operation concentrates and quickly dissipates the heat away from the resonant layer 140. An additional conductive material layer 115′ may be formed at a position corresponding to the second area R₂.

Turning to FIG. 2, a first solder layer 119a is formed on the conductive material layer 115 and contacts the first area R₁ of the light-emitting element 180. A diffusion prevention layer 117 is formed between the first solder layer 119a and the first area R₁ of the light-emitting element 180. When tin (Sn) contained in the first solder layer 119a is diffused into the conductive material layer 115, the conductive material layer 115 or the submount 111 may be damaged due to stress exerted on the conductive material layer 115 and its repeated expansion and contraction according to changes in the on/off status of the light-emitting element 180. The diffusion prevention layer 117 may be formed of Pt, for example. A second solder layer 119b is formed on the submount 111 having no groove 111′ (or a groove with a conductive material layer 115″ as shown in FIG. 3) and bonded to the second area R₂ of the light-emitting element 180. The metal medium layer 113 and the diffusion prevention layer 117 may be sequentially formed between the second solder layer 119b and the submount 111.

Sn-based solders such as Au/Sn or Sn/Ag may be used in forming the first and second solder layers 119a and 119b. The heat dissipating structure 100 and the light-emitting element 180 are aligned vertically so that the first and second solder layers 119a and 119b oppose the p- and n-type electrodes 121 and 122, respectively, and bonded to each other by applying ultrasonic wave and appropriate pressure.

In order to verify the effect of the present disclosure, computerized data was analyzed to find that the submount 111 of the present disclosure has a more uniform temperature gradient than a conventional submount because the conductive material layer 115 formed in the groove 111′ acts to widely diffuse heat. In this way, the present disclosure allows uniform dispersion of heat generated in the light-emitting element 180 over the entire submount 111, thus decreasing the temperature of the light-emitting element 180. Experiments showed that average temperature in the first area R₁ is tens of percent lower than temperature observed for a conventional structure

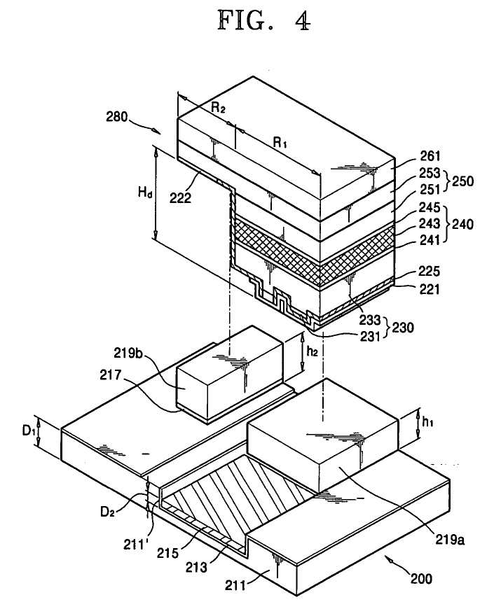

FIG. 4 is a perspective view of a light-emitting device according to a second embodiment of the present disclosure. Referring to FIG. 4, like the light-emitting device of FIG. 2, the light-emitting device includes a light-emitting element 280 and a heat dissipating structure 200 flip-chip bonded to the light-emitting element 280. The light-emitting element 280 includes a substrate 261, and an upper material layer 250, a resonant layer 240 and a lower material layer 230 sequentially formed beneath the substrate 261 at first area R₁. The upper material layer 250 has a stepped structure that extends to a second area R₂. The resonant layer 240 allows laser light to oscillate due to light energy created by recombination of carriers and the upper and lower material layers 250 and 230 are electrically connected to n- and p-type electrodes 222 and 221, respectively. The p-type electrode 221 is formed in the lowermost portion of the first area R₁ and coupled to the lower material layer 230 exposed by a current limiting layer 225. On the other hand, the n-type electrode 222 is formed in and connected to the upper material layer 250 at the second area R₂. Because the light-emitting element 280 has a stepped structure, a height difference H_{d} between the first and second areas R₁ and R₂ occurs.

The heat dissipating structure 200 flip-chip bonded to the light-emitting element 280 includes a submount 211 and solder layers 219a and 219b that is formed on the submount 211 and creates a heat dissipating path for dissipating heat away from the light-emitting element 280. The submount 211 has a groove 211′ formed therein. A conductive material layer 215 formed within the groove 211′ acts to uniformly diffuse heat energy transferred from the light-emitting element 280 during operation over the submount 211. The conductive material layer 215 is filled to a depth D₂ that is a part of the entire depth D₁ so that the top surface of the first solder layer 219a is stepped with respect to the top surface of the second solder layer 219b.

The heat dissipating structure 200 flip-chip bonded to the light-emitting element 280 has a step height to compensate for the step height of the light-emitting element 280. A predetermined height difference may occur between the first solder layer 219a welded to the p-type electrode 221 at the thick-film first area R₁ and the second solder layer 219b welded to the n-type electrode 222 at the thin-film second area R₂. That is, the height h2 of the second solder layer 219b may be greater than the height h1 of the first solder layer 219a. When an excessive height difference occurs between the first and second solder layers 219a and 219b, a melted state of solder may vary between the first and second solder layers 219a and 219b during a reflow process, thereby resulting in a lopsided light-emitting device or incomplete support structure thus a damage within the light-emitting element 280.

In the present embodiment, the groove 211′ is formed in the submount 211 to a predetermined depth in such a manner as to cause a step difference between the top surfaces of the solder layers 219a and 219b that will compensate for the step height of the light-emitting device while reducing or eliminating a height difference between the solder layers.

A metal medium layer 213 is interposed between the conductive material layer 215 formed within the groove 211′ and the submount 211 and a diffusion prevention layer 217 is formed between the conductive layer 215 and either the first or second solder layer 219a or 219b in this exemplary embodiment. A first material layer 253 and an upper cladding layer 251 contained in the upper material layer 250, an upper waveguide layer 245, an active layer 243 and a lower waveguide layer 241 contained in the resonant layer 240, and an upper cladding layer 233 and a second material layer 231 contained in the lower material layer 230 have substantially the same or similar configurations and functions as their counterparts of the light-emitting device of FIG. 2, a detailed explanation thereof will not be given.

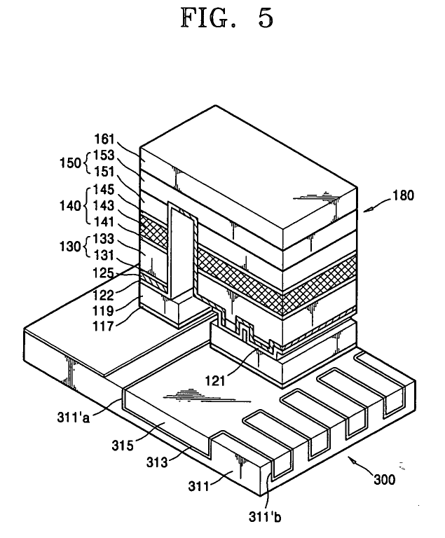

FIG. 5 is a perspective view of a light-emitting device according to a third embodiment of the present disclosure. Like reference numerals in FIGS. 2 and 5 denote like elements. Referring to FIG. 5, a submount 311 has a first groove 311′a formed along one direction and a plurality of second grooves 311′b arranged perpendicular to the length of the first groove 311′a. The first and second grooves 311′a and 311′b are filled with a conductive material layer 315 that rapidly diffuses heat along the plane of the submount 311. The conductive material layers 315 are formed in the two orthogonal directions to facilitate two-dimensional heat diffusion. The heat transferred to the submount 311 is dissipated by natural convection through the outer surface of the submount 311. In this case, heat uniformly transferred to the entire outer surface of the submount 311 is efficiently dissipated through a wide heat transfer area. A metal medium layer 313 may be formed between the conductive material layer 315 and the submount 311 and the diffusion prevention layer 117 may be interposed between the conductive material layer 315 and the solder layer 119.

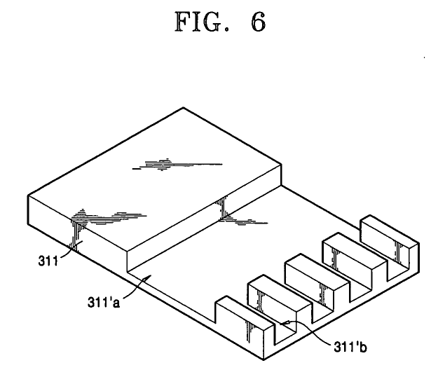

FIG. 6 is a perspective view of the submount 311 shown in FIG. 5. Referring to FIG. 6, the second grooves 311′b are arranged at predetermined intervals perpendicular to the length of the first groove 311′a of the submount 311. The first and second grooves 311′a and 311b′ may be formed by photo-lithography and wet or dry etching.

Although in the above description a laser diode is used as a light-emitting element, it will be readily apparent to those skilled in the art that a light-emitting diode may be the light-emitting element.

The exemplary embodiments of heat dissipating structure and light-emitting device including the same according to the present disclosure have several advantages. First, a conductive material layer formed in the submount allows heat generated in a light-emitting element during operation to be rapidly diffused, thus preventing degradation of the light-emitting element while achieving a high output power light-emitting element with improved light-emission characteristics and high injection current. Second, a groove is formed in the submount flip-chip bonded to the stepped light-emitting element, thereby creating a step difference to compensate for the step height of the light-emitting element while reducing or eliminating the height difference between solder layers. This makes the melted state of solders in the solder layers uniform during reflow-soldering, thereby preventing damage within the light-emitting element during bonding.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A heat dissipating structure that is flip-chip bonded to a light-emitting element and facilitates heat dissipation, the heat dissipating structure comprising:
a submount facing the light-emitting element and having at least one groove;
a conductive material layer located in at least a portion of the at least one groove; and
a solder layer interposed between the light-emitting element and the conductive material located in the groove of the submount for bonding.

2. The heat dissipating structure of claim 1, wherein the conductive material layer contains at least one metal selected from the group consisting of gold (Au), copper (Cu), copper (Cu) alloy, copper-tungsten (Cu—W) alloy, silver (Ag), and aluminum (Al) alloy.

3. A light-emitting device comprising:
a light-emitting element including an upper material layer, a lower material layer, and a resonant layer that is interposed between the upper and lower material layers and emits light;
a submount that is disposed to vertically face the light-emitting element and has at least one groove;
a conductive material layer located in at least a portion of the at least one groove; and
a solder layer interposed between the light-emitting element and the conductive material layer of the submount for bonding.

4. The light-emitting device of claim 3, wherein the conductive material layer contains at least one metal selected from the group consisting of gold (Au), copper (Cu), copper (Cu) alloy, copper-tungsten (Cu—W) alloy, silver (Ag), and aluminum (Al) alloy.

5. The light-emitting device of claim 3, further comprising a metal medium layer interposed between the submount and the conductive material layer.

6. The light-emitting device of claim 5, wherein the metal medium layer is formed to cover at least the inside of the groove.

7. The light-emitting device of claim 5, wherein the metal medium layer contains at least one metal selected from the group consisting of titanium (Ti), platinum (Pt), and gold (Au).

8. The light-emitting device of claim 1, further comprising a diffusion prevention layer interposed between the conductive material layer and the solder layer.

9. The light-emitting device of claim 8, wherein the diffusion prevention layer includes Pt.

10. The light-emitting device of claim 3, wherein the ratio of thickness t2 of the conductive material layer to thickness t1 of the submount is greater than 46%.

11. The light-emitting device of claim 3, wherein the light-emitting element includes a first region containing the resonant layer and a second region that is separated from the first region by a gap, and
wherein the solder layer includes a first solder layer bonded to the first region and a second solder layer bonded to the second region.

12. The light-emitting device of claim 11, wherein the conductive material layer vertically faces at least the first region and creates a heat dissipating path for dissipating heat away from the resonant layer.

13. The light-emitting device of claim 11, wherein the first and second regions are stacked to substantially the same thickness and the top surface of the first solder layer facing the first region are at substantially the same level as the top surface of the second solder layer facing the second region.

14. The light-emitting device of claim 11, wherein the first and second regions are formed to a different thickness and the top surfaces of the first and second solder layers have a step height that compensates for a step difference between the first and second regions.

15. The light-emitting device of claim 11, wherein the submount has a first groove formed along one direction and a plurality of second grooves arranged at predetermined intervals perpendicular to the length of the first groove.

16. The light-emitting device of claim 3, wherein the light-emitting element is one of a laser diode (LD) and a light-emitting diode (LED).

17. The light-emitting device of claim 3, wherein the solder layer is formed of one of Sn-based alloys Au/Sn and Sn/Ag.

18. The light-emitting device of claim 3, wherein the submount is formed of one of insulating materials that are aluminum nitride (AlN), silicon carbide (SiC), aluminum (Al), and silicon (Si).
